(19) United States
(12) Patent Application Publication
(10) Pub. No.: US 2018/0151812 A1
(43) Pub. Date: May 31, 2018

(54) OLED DISPLAY DEVICE and MANUFACTURING METHOD THEREOF

(71) Applicant: Shenzhen China Star Optoelectronics Technology Co. Ltd., Shenzhen City (CN)

(72) Inventors: Qiming Peng, Shenzhen City (CN); Xianjie Li, Shenzhen City (CN)

(21) Appl. No.: 15/120,742

(22) PCT Filed: May 19, 2016
(86) PCT No.: PCT/CN2016/082700

§ 371 Date: Aug. 23, 2016

(30) Foreign Application Priority Data
Apr. 15, 2016 (CN) 201610235382.5

(51) Int. Cl. H01L 51/00

(52) U.S. Cl. CPC H01L 51/0077; H01L 51/5246; H01L 51/0072

(57) ABSTRACT

The present application discloses an OLED display device and its manufacturing method thereof, the OLED display device includes a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate; wherein the material of the electron transporting layer is a mixture of an organic electron transporting material and an organometal halide perovskite material. By using the mixture of an organic electron transporting material and an organometal halide perovskite material to form the electron transporting layer can enhance electron mobility of the electron transporting layer, balance the injection transport of carrier of the OLED display device, increase the light emitting efficiency, reduce the difficulty of film formation and improve film quality, to ensure the stability of the OLED display.

### FIELD OF THE INVENTION

The present application relates to a display technology field, and more particularly to an OLED display device and manufacturing method thereof.

### BACKGROUND OF THE INVENTION

Organic light emitting display, OLED display device has self-luminous, low driving voltage, high luminous efficiency, short response time, clarity and high contrast, near 180° viewing angle, wide range using temperature, can be achieved with flexible display and large size of full-color display and many other advantages, is widely and worldly recognized as the most potential development of the display device.

OLED display devices are self-luminous type display device, typically including pixel electrodes used as an anode and a cathode, and the common electrode, an organic light emitting layer disposed between the pixel electrode and the common electrode, so that when an appropriate voltage is applied to the anode and cathode, the organic light emitting layer will emit light. The organic light emitting layer includes a hole injection layer disposed on the anode, a hole transport layer disposed on the hole injection layer, a light emitting layer formed on the hole transport layer, an electron transporting layer provided on the light emitting layer, an electron injection layer formed on the electron transporting layer. Its light emission mechanism is driven by a certain voltage, electrons and holes are injected from the anode and the cathode to the electron injection layer and the hole injection layer, electrons and holes are through the electron transporting layer and the hole transport layer respectively, migrating to the light emitting layer and meet in the light emitting layer, the excitons are formed to excite the luminescent molecules, the latter emit visible light through radiative relaxation.

Although the OLED display devices had achieved commercial production, but its luminous efficiency is still a large room for improvement. In the conventional technology, the electron transporting layer and the hole transport layer in the OLED display device are organic layers. The electron mobility of the electron transporting layer is usually much lower than the hole mobility of the hole transporting layer, leading to the transmission imbalance of the internal non-equilibrium carrier, thereby reducing the luminous efficiency of the OLED display device.

Organometal halide perovskites materials are a semiconductor material considered to be having excellent optical properties, which have a long carrier diffusion length (up to 1 μm), high carrier mobility (about 10 cm²/Vs), both inorganic semiconductor optical characteristics and advantages of low deposition temperature of organic material, and is ideal for industrial production of low-cost, large size and the flexible substrate device.

However, the current technology for preparing high quality organometal halide perovskite thin films is relatively difficult. Therefore, it is necessary to develop new and binding organometal halide perovskite materials. The manufacturing process is relatively simple, high stability, with good film quality, with balanced carrier injection and transporting OLED display device.

### SUMMARY OF THE INVENTION

The purpose of the present application is to provide an OLED display device to increase the light emitting efficiency of the OLED display device and improve the quality of the OLED display device.

The further purpose of the present application is to provide a manufacturing method of the OLED display device to have good film quality in simple and quick production capacity, balanced injection transport of carrier, and high light emitting efficiency.

In order to achieve the purpose mentioned above, an An OLED display device is provided in the present application, including a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate;

the material of the electron transporting layer is a mixture of an organic electron transporting material and an organometal halide perovskite material.

wherein the mixing mass ratio of the mixture of the organic electron transporting material and the organometal halide perovskite material is 1:0.5 to 1:50.

wherein the material of the organic electron transporting material is selected from metal complex material or imidazoles electron transporting material.

wherein the structural formula of the organometallic halide perovskite material is: CH₃NH₃PbA₃, wherein A is selected from one or a combination of Chlorine, Bromine, or Iodine.

wherein the thickness of the electron transporting layer is between 10 to 100 nm.

A method for manufacturing an OLED display device is also provided in the present application includes the steps of:

Step1: providing a substrate, an anode, a hole injection layer, a hole transport layer, a light emitting layer, and a hole blocking layer are formed in this order on the substrate;

Step 2: a mixture of organic electron transporting material and organometal halide perovskite material is provided, and an electron transporting layer is formed with the material of the mixture of organic electron transporting material and organometal halide perovskite material on the hole blocking layer;

Step 3: an electron injection layer is formed on the electron transporting layer, and a cathode is formed on the electron injection layer; and

Step 4: a sealing adhesive material is coated on the edge of the substrate, forming a circle of the sealing adhesive material, a cover plate is provide to cover the substrate and adhesion to the substrate by the sealing adhesive material, and the cover plate is disposed opposite to the substrate.

wherein the mixing mass ratio of the mixture of the organic electron transporting material and the organometal halide perovskite material is 1:0.5 to 1:50.

wherein the material of the organic electron transporting material is selected from metal complex material or imidazoles electron transporting material.

wherein the structural formula of the organometallic halide perovskite material is: CH₃NH₃PbA₃, wherein A is selected from one or a combination of Chlorine, Bromine, or Iodine.

wherein the electron transporting layer in step 2 is formed by a wet deposition formation process with the thickness between 10 to 100 nm.

An OLED display device is provide in the present application including a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate;

the material of the electron transporting layer is a mixture of an organic electron transporting material and an organometal halide perovskite material; and

wherein the mixing mass ratio of the mixture of the organic electron transporting material and the organometal halide perovskite material is 1:0.5 to 1:50; and

wherein the thickness of the electron transporting layer is between 10 to 100 nm.

The advantage of the present application: an OLED display device is provided in the present application includes a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate; wherein the material of the electron transporting layer is a mixture of an organic electron transporting material and an organometal halide perovskite material. By using the mixture of an organic electron transporting material and an organometal halide perovskite material to form the electron transporting layer can enhance electron mobility of the electron transporting layer, balance the injection transport of carrier of the OLED display device, increase the light emitting efficiency, reduce the difficulty of film formation and improve film quality, to ensure the stability of the OLED display. A manufacturing method of the OLED display device is provide in the present application to have good film quality in simple and quick production capacity, balanced injection transport of carrier, and high light emitting efficiency.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 illustrates a schematic structure of an OLED display device according to an embodiment of the present application; and

FIG. 2 illustrates the manufacturing flow of the OLED display device according to a manufacturing method of an embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

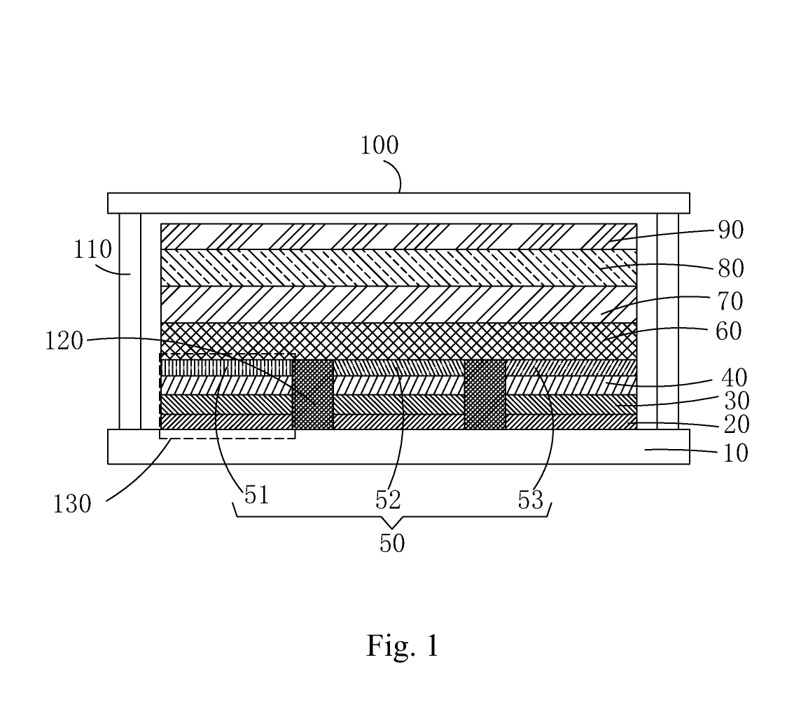

Refer to FIG. 1, an OLED display device is provided in the present application including a substrate 10, an anode 20 formed on the substrate 10, a hole injection layer 30 formed on the anode 20, a hole transport layer 40 formed on the hole injection layer 30, a light emitting layer 50 formed on the hole transport layer 40, a hole blocking layer 60 formed on the light emitting layer 50, an electron transporting layer 70 formed on the hole blocking layer 60, an electron injection layer 80 formed on the electron transporting layer 70, a cathode 90 formed on the electron injection layer 80, a cover plate 100 disposed opposite to and cover the substrate 10, and a sealing adhesive material 110 formed between the edge of the substrate 10 and the cover plate 100.

The material for the electron transporting layer 70 is a mixture of an organic electron transporting material and an organometal halide perovskite material.

In particular, in the mixture of the organic electron transporting material and an organometal halide perovskite material, the mixing mass ratio of the organic electron transporting material and the organometal halide perovskite material is 1:0.5 to 1:50. The material of the organic electron transporting material is selected from metal complex material such as tris (8-quinolinolato) aluminum, Alq3, etc., or selected from imidazoles electron transporting material such as 1,3,5-Tris (1-phenyl-1H-benzimidazol-2-yl) benzene, TPBi, etc. The structural formula of the organometallic halide perovskite material is: CH₃NH₃PbA₃, wherein A is selected from one or a combination of Chlorine, Bromine, or Iodine. The electron transporting layer 70 is prepared using a wet deposition formation process, the thickness of the film is between 10 to 100 nm. A mixture of the organic electron transporting material and the organometal halide perovskite material to form the electron transporting layer 70 compared to a single organic electron transporting material can enhance electron mobility of the electron transporting layer, balance the injection transport of carrier of the OLED display device. Compared to the single organometal halide perovskite materials can reduce the difficulty of film formation and improve film quality, to ensure the stability of the OLED display.

Wherein the molecular structure of the TPBi is as follows:

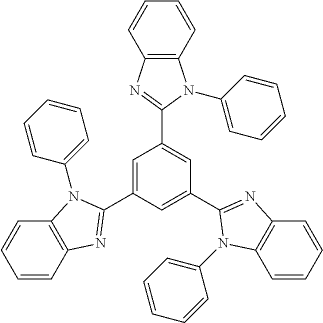 [SMILES: c1ccc(-n2c(-c3cc(-c4nc5ccccc5n4-c4ccccc4)cc(-c4nc5ccccc5n4-c4ccccc4)c3)nc3ccccc32)cc1]

Further, the OLED display device includes a plurality of pixels 130 formed on the substrate 10 arranged in arrays. Each pixel 130 includes a plurality of light emitting units, each light emitting unit 120 is spaced apart from the pixel isolation layer 130, an opening is formed on the pixel isolation layer 120 and penetrating the pixel isolation layer 120, each opening is corresponding to the light emitting unit 130. The anode 20, the hole injection layer 30, the hole transport layer 40, and the light emitting layer 50 of each light emitting unit 130 are located within the opening of its corresponding pixel isolation layer 120. Such as the anode 20, the hole injection layer 30, the hole transport layer 40, and the light emitting layer 50 are separately formed corresponding to each light emitting unit 130. And the hole blocking layer 60, the electron transporting layer 70, the electron injection layer 80, and the cathode 90 can be integrally sequentially formed on the light emitting layer 50 and the pixel isolation layer 120, wherein the hole blocking layer 60 can be formed respectively corresponding to each light emitting unit 130. Similarly, the electron transporting layer 70 can be formed respectively corresponding to each light emitting unit 130. Preferably, each pixel includes: a red light emitting unit, a green light emitting unit, a blue light emitting unit, the light emitting layer of the red light emitting unit, the green light emitting unit, the blue light emitting unit are a red light emitting layer 51, a green light emitting layer 52 , and a blue light emitting layer 53 respectively. The material of the hole injection layer 20 corresponding to the red, the green, and the blue light emitting unit can be the same material or different materials, and their thickness can be the same or can be different. The material of the hole injection layer 30 corresponding to the red, the green, and the blue light emitting unit can be the same material or different materials, and their thickness can be the same or can be different. The material of the hole blocking layer 60 corresponding to the red, the green, and the blue light emitting unit can be the same material or different materials, and their thickness can be the same or can be different. The material of the electron transporting layer 70 corresponding to the red, the green, and the blue light emitting unit can be the same material or different materials, and their thickness can be the same or can be different. If the light emitting layer 50 corresponding to the red, the green, and the blue light emitting unit is a combined host-guest doping type, the host-guest doping ratio can be the same or can be different, their thickness can be the same or can be different, and the material of the main can be the same or can be different.

Note that, the substrate 10 is a Thin Film Transistor, TFT array substrate including a base substrate, and the TFT array formed on the base substrate, preferably, the base substrate can be a glass substrate with high visible light transmittance.

Specifically, the material of the sealing adhesive material 110 is an epoxy resin or UV glue, preferably an epoxy resin; the material of the cover plate 100 is quartz glass or metal, preferably quartz glass.

The material of the anode 20 is selected from transparent conductive metal oxides, such as Indium Tin Oxide, ITO, Indium Zinc Oxide, IZO, or etc., or a metal with high work function or an alloy with high work function, such as gold (Au), platinum (Pt), silver (Ag) or etc. The material of the anode can be used alone, can also be used in combination of two or more, the film thickness of the anode 20 is between 20 nm and 200 nm.

The hole injection layer 30 is used to assist holes inject from the anode 20 to the hole transport layer 40. The material of the hole injection layer 30 can be an organic small molecule hole injecting material, such as Dipyrazino [2,3-f: 2′, 3′-h] quinoxaline-2,3,6,7,10,11-hexacarbonitrile, HATCN, etc., or a polymer hole injection material, such as Poly(3,4-ethylenedioxythiophene)-poly(styrenesulfonate), PEDOT: PSS, etc., or a metal oxide hole injection material, such as Molybdenum Trioxide, MoO₃, etc., and the thickness of the hole injection layer 30 is between 1 nm and 100 nm.

Wherein the molecular structure of the HATCN is as follows:

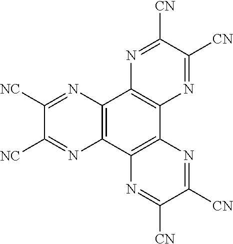 [SMILES: N#Cc1nc2c3nc(C#N)c(C#N)nc3c3nc(C#N)c(C#N)nc3c2nc1C#N]

The hole transport layer 40 is used to inject holes from the hole transport layer 30 to the light emitting layer 50, the material of the hole transport layer 40 is an organic small molecule hole transporting material such as N, N′-Bis-(1-naphthalenyl)-N, N′-bis-phenyl-(1,1′-biphenyl)-4,4′-diamine, NPB, or (4,4′-yclohexylidenebis [N, N-bis (p-tolyl) aniline], TAPC, or etc., or a polymer hole transporting material such as poly [bis (4-phenyl) (4-butylphenyl) amine], Poly-TPD, etc., and the thickness is between 10 nm to 100 nm.

Wherein the molecular structure of the NPB is as follows:

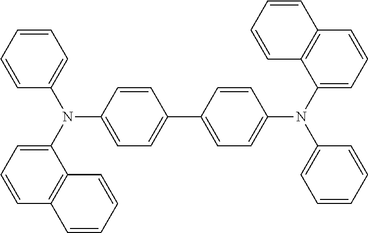 [SMILES: c1ccc(N(c2ccc(-c3ccc(N(c4ccccc4)c4cccc5ccccc45)cc3)cc2)c2cccc3ccccc23)cc1]

The light emitting layer 50 is divided into three types such as the red light emitting layer 51, the green light emitting layer 52 and the blue light emitting layer 53. The electrons and holes are combined and emitted light in the light emitting layer 50, the material can be selected from an organic small molecule fluorescent material, or an organic polymeric fluorescent material, a small molecule phosphorescent material or a polymer phosphorescent material. The light emitting layer 50 can be a combined host-guest doping type or undoped type and having a thickness of 5 nm to 50 nm. The hole blocking layer 60 is used to block holes from the light emitting layer 50 to inject to the electron transporting layer 70, while the hole blocking layer 60 can also transport electrons. The material of the hole blocking layer 60 can be selected from the organic small molecule material or a polymer having low highest occupied molecular orbital, HOMO, such as 2, 9-dimethyl-4,7-diphenyl-1,10-Phenanthroline, BCP, etc., and with a thickness of 2 nm to 20 nm.

Wherein the molecular structure of the BCP is as follows:

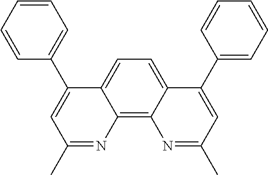 [SMILES: Cc1cc(-c2ccccc2)c2ccc3c(-c4ccccc4)cc(C)nc3c2n1]

The electron injection layer 80 is used to help electron inject from the cathode 90 to the electron transporting layer 70, the material can be selected from metal complexes such as 8-Hydroxyquinolinolato-lithium, Liq, etc., or an alkali metal and its salts, such as Lithium (Li), Sodium (Na), Potassium (K), Rubidium (Rb), Cesium (Cs), Lithium Fluoride (LiF), Lithium Carbonate (Li₂CO₃), Lithium Chloride (LiCl), Sodium Fluoride (NaF), Sodium Carbonate (Na₂CO₃), Sodium Chloride (NaCl), Cesium Fluoride (CsF), Cesium Carbonate (Cs₂CO₃), and Cesium Chloride (CsCl), etc., or alkaline earth metal or its salts, such as Magnesium (Mg), Calcium (Ca), Strontium (Sr), Barium (Ba), Calcium Fluoride (CaF₂), Calcium Carbonate (CaCo₃), Strontium Fluoride (SrF₂), Strontium Carbonate (SrCo₃), Fluorinated Barium (BaF₂), and Barium Carbonate (BaCo₃), Etc. The above materials can be used singly or in combination of two or more to form the electron injection layer 80 with its thickness between 0.5 nm to 10 nm

The material of the cathode 90 is a low work function metal material e.g., Lithium (Li), Magnesium (Mg), Calcium (Ca), Strontium (Sr), Lanthanum (La), Cerium (Ce), Europium (Eu), Ytterbium (Yb), Aluminum (Al), Cesium (Cs), Rubidium (Rb), etc., or an alloy of low work function. The material of the cathode 90 can be used alone, it can also be used in combination of two or more material. The cathode 90 is formed by a vacuum deposition film forming method, with a thickness of between 10 nm to 1000 nm. For example, in a preferred embodiment of the present application, the material of the anode 20 is ITO with a thickness of 90 nm; the material of the hole injection layer 30 is HATCN with a thickness of 10 nm; the material of the hole transport layer 40 is NPB with a thickness of 30 nm. The light emitting layer 50 includes the red light emitting layer 51, the green light emitting layer 52, and the blue light emitting layer 53 with a film thickness of 20 nm. The material is a combined host-guest doping type, wherein the host material of the blue light emitting layer 53 is 1,3-Di-9-carbazolylbenzene, mCP, a guest material of the blue light emitting layer 53 is Bis (4,6-difluorophenyl pyridine-N, C2), bis [2-(4,6-difluorophenyl) pyridinato-C2, N] (picolinato) iridium (III), FlrPic. The host material of the green light emitting layer 52 is 4,4′-Bis (N-carbazolyl)-1,1′-biphenyl, CBP; a guest material of the green light emitting layer 52 is Tris (2-phenylpyridinato-C2, N) iridium (III), Ir (ppy)₃. The host material of the red light emitting layer 51 is CBP, a guest material of the red light emitting layer 51 is:

Bis (1-phenyl-isoquinoline-C2, N) (acetylacetonato) iridium (III), Ir (piq)₂ (acac). The material of the hole blocking layer 60 is BCP with a film thickness of 10 nm. The material of the electron transporting layer 70 includes an organic electron transporting material: TPBi and an organometallic halide perovskite material: CH₃NH₃PbI₂Cl, that is Methylammonium lead Chloride Iodide with thickness of 50 nm. The mix ratio of the organic electron transporting material and the organometallic halide perovskite material in the electron transporting layer 70 is 1:9. The material of the electron injecting material layer 80 is LiF with thickness of 1 nm. The material of the cathode 90 is Al with a film thickness of 200 nm.

Wherein the molecular structure mCP is as follows:

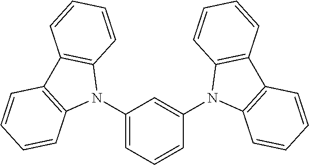 [SMILES: c1cc(-n2c3ccccc3c3ccccc32)cc(-n2c3ccccc3c3ccccc32)c1]

Wherein the molecular structure FlrPic is as follows:

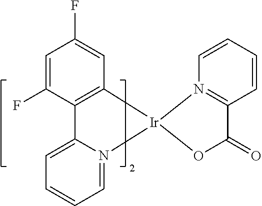

Wherein the molecular structure CBP is as follows:

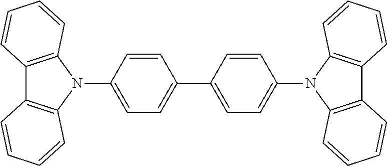 [SMILES: c1ccc2c(c1)c1ccccc1n2-c1ccc(-c2ccc(-n3c4ccccc4c4ccccc43)cc2)cc1]

Wherein the molecular structure Ir(ppy)₃ is as follows:

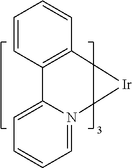

Wherein the molecular structure Ir(piq)₂(acac) is as follows:

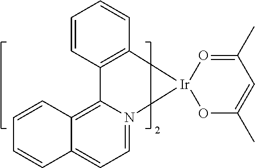

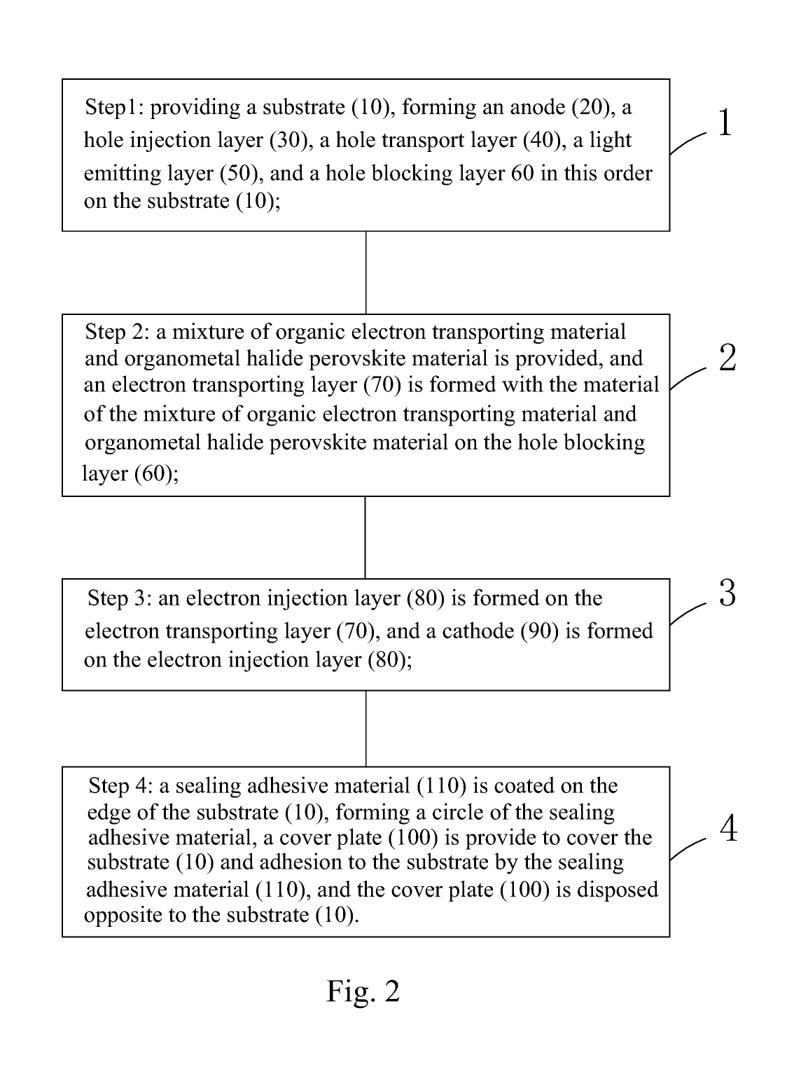

Referring to FIG. 2, the present application also provides a method of manufacturing an OLED display device including the steps of:

Step 1: Referring to FIG. 1, a substrate 10 is provided, an anode 20, a hole injection layer 30, a hole transport layer 40, a light emitting layer 50, and a hole blocking layer 60 are formed in this order on the substrate.

Wherein, the substrate 10 is a TFT array substrate including a base substrate, and the TFT array formed on the base substrate, preferably, the base substrate can be a glass substrate with high visible light transmittance.

The material of the anode 20 is selected from transparent conductive metal oxides or a metal with high work function, such as ITO. The manufacturing method is magnetron sputtering method, with a film thickness of 20 nm to 200 nm, preferably 90 nm film thickness.

The material of the hole injection layer 30 is an organic small molecule hole injection material, a polymer hole injection material, or a metal oxide hole injection material, preferably is HATCN. The manufacturing method is vacuum deposition method or a wet deposition formation process, e.g., inkjet printing, nozzle printing, etc. with a film thickness of 1 nm to 100 nm, preferably a thickness of 10 nm.

The material of the hole transport layer 40 is an organic small molecule hole transport material, or a polymer hole transport material. The manufacturing method is vacuum deposition method or a wet deposition formation process, preferably is NPB, with a film thickness of 5 nm to 50 nm.

The material of the light emitting layer 50 organic small molecule fluorescent material, polymeric fluorescent material, small molecule phosphorescent material or polymer phosphorescent material. The manufacturing method is vacuum deposition method or a wet deposition formation process, with a film thickness of 5 nm to 50 nm.

Preferably, the light emitting layer 50 includes the blue light emitting layer 53, the green light emitting layer 52, and the red light emitting layer 51 with a combined host-guest doping type structure. The host material are mCP, CBP, and CBP separately; the guest material are FlrPic, Ir (ppy)₃, and Ir (piq)₂(acac) separately, with a doping ratio: 8%, 6% and 4%; and the thickness are both 20 nm.

The material of the hole blocking layer 60 is organic small molecule material or a polymer having low highest occupied molecular orbital, HOMO, preferably is BCP. The manufacturing method is vacuum deposition method or a wet deposition formation process, with a film thickness of 2 nm to 20 nm, preferably a thickness of 10 nm.

Step 2: a mixture of organic electron transporting material and organometal halide perovskite material is provided, the electron transporting layer 70 is formed with the mixture of organic electron transporting material and organometal halide perovskite material on the hole blocking layer 60.

In particular, the mixing mass ratio of organic electron transporting material and organometal halide perovskite material is 1:0.5 to 1:50. Alternatively the organic electron transporting material is metal complex material, or imidazoles electron transporting material. The structural formula of the organometallic halide perovskite material is: CH₃NH₃PbA₃, wherein A is Chlorine, Bromine, and Iodine, or a combination of one more thereof. The electron transporting layer 70 is formed by wet deposition formation process with a thickness between 10 nm to 100 nm. Preferably, the material of the electron transporting layer 70 is 10% TPBi and 90% CH₃NH₃PbI₂Cl with a film thickness of 50 nm.

It notes that, by using a mixture of organic electron transporting material and organometallic halide perovskite material to produce the electron transporting layer 70, compared to a single organic electron transporting material can enhance electron mobility of the electron transporting layer, balance the injection transport of carrier of the OLED display device. Compared to the single organometal halide perovskite materials can reduce the difficulty of film formation and improve film quality, to ensure the stability of the OLED display.

Step 3: the electron injection layer 80 is formed on the electron transporting layer 70, a cathode 90 is formed on the electron injection layer 80.

The electron injection layer 80 is used to help electron inject from the cathode 90 to the electron transporting layer 70. The material of the electron injection layer 80 is metal complexes, alkali metal and its salts, or alkaline earth metal or its salts. The above materials can be used singly or in combination of two or more to form the electron injection layer 80, preferably is LiF. The manufacturing method is vacuum deposition method, with a film thickness of 0.5 nm to 10 nm, preferably a thickness of 1 nm.

The material of the cathode 90 is a low work function metal material, or an alloy of low work function, the material can be used alone or in combination of two or more, preferably is Al, The manufacturing method is vacuum deposition method, with a film thickness of 10 nm to 1000 nm, preferably a thickness of 200 nm.

Step 4: the sealing adhesive material 110 is provided and coating on the edge of the substrate 10, forming a circle surrounding and covering the anode 20, the hole injection layer 30, the hole transport layer 40, the light emitting layer 50, the hole blocking layer 60, the electron transporting layer 70, the electron injection layer 80, and the cathode 110. The cover plate 100 is provide, the cover plate 100 is covered the substrate and adhesion to the substrate by the sealing adhesive material 110, and the cover plate 100 is disposed opposite to the substrate 10.

Specifically, the material of the sealing adhesive material 110 is an epoxy resin or UV glue, preferably an epoxy resin; the material of the cover plate 100 is quartz glass or metal, preferably quartz glass.

In summary, an OLED display device is provided in the present application, including the substrate, the anode formed on the substrate,

the hole injection layer formed on the anode, the hole transport layer formed on the hole injection layer, the light emitting layer formed on the hole transport layer, the hole blocking layer formed on the light emitting layer, the electron transporting layer formed on the hole blocking layer, the electron injection layer formed on the electron transporting layer, the cathode formed on the electron injection layer, the cover plate disposed opposite to and cover the substrate, and the sealing adhesive material formed between the edge of the substrate and the cover plate. Wherein the material of the mixture of the organic electron transporting material and the organometal halide perovskite material is adopted to form the electron transporting layer. By using the mixture of the organic electron transporting material and the organometal halide perovskite material to form the electron transporting layer can enhance electron mobility of the electron transporting layer, balance the injection transport of carrier of the OLED display device, increase the light emitting efficiency, reduce the difficulty of film formation and improve film quality, to ensure the stability of the OLED display. The present application also provides a method of manufacturing an OLED display device with good film quality in simple and quick production capacity, balanced injection transport of carrier, and high light emitting efficiency of the OLED display device.

Above are embodiments of the present application, which does not limit the scope of the present application. Any modifications, equivalent replacements or improvements within the spirit and principles of the embodiment described above should be covered by the protected scope of the invention.

What is claimed is:

1. An OLED display device, comprising
a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate; and
the material of the electron transporting layer is a mixture of an organic electron transporting material and an organometal halide perovskite material.

2. The OLED display device according to claim 1, wherein the mixing mass ratio of the mixture of the organic electron transporting material and the organometal halide perovskite material is 1:0.5 to 1:50.

3. The OLED display device according to claim 2, wherein the material of the organic electron transporting material is selected from metal complex material or imidazoles electron transporting material.

4. The OLED display device according to claim 2, wherein the structural formula of the organometallic halide perovskite material is: CH₃NH₃PbA₃, wherein A is selected from one or a combination of Chlorine, Bromine, or Iodine.

5. The OLED display device according to claim 1, wherein the thickness of the electron transporting layer is between 10 to 100 nm.

6. A method for manufacturing an OLED display device, comprising the steps of:
Step1: providing a substrate, an anode, a hole injection layer, a hole transport layer, a light emitting layer, and a hole blocking layer are formed in this order on the substrate;
Step 2: a mixture of organic electron transporting material and organometal halide perovskite material is provided, and an electron transporting layer is formed with the material of the mixture of organic electron transporting material and organometal halide perovskite material on the hole blocking layer;
Step 3: an electron injection layer is formed on the electron transporting layer, and a cathode is formed on the electron injection layer; and
Step 4: a sealing adhesive material is coated on the edge of the substrate, forming a circle of the sealing adhesive material, a cover plate is provide to cover the substrate and adhesion to the substrate by the sealing adhesive material, and the cover plate is disposed opposite to the substrate.

7. The method for manufacturing an OLED display device according to claim 6, wherein the mixing mass ratio of the mixture of the organic electron transporting material and the organometal halide perovskite material is 1:0.5 to 1:50.

8. The method for manufacturing an OLED display device according to claim 7, wherein the material of the organic electron transporting material is selected from metal complex material or imidazoles electron transporting material.

9. The method for manufacturing an OLED display device according to claim 7, wherein the structural formula of the organometallic halide perovskite material is: CH₃NH₃PbA₃, wherein A is selected from one or a combination of Chlorine, Bromine, or Iodine.

10. The method for manufacturing an OLED display device according to claim 6, wherein the electron transporting layer in step 2 is formed by a wet deposition formation process with the thickness between 10 to 100 nm.

11. An OLED display device, comprising
a substrate; an anode formed on the substrate; a hole injection layer formed on the anode; a hole transport layer formed on the hole injection layer; a light emitting layer formed on the hole transport layer; a hole blocking layer formed on the light emitting layer; an electron transporting layer formed on the hole blocking layer; an electron injection layer formed on the electron transporting layer; a cathode formed on the electron injection layer; a cover plate disposed opposite to and cover the substrate; and a sealing adhesive material formed between the edge of the substrate and the cover plate;
the material of the electron transporting layer is a mixture of an organic electron transporting material and an organometal halide perovskite material; and
wherein the mixing mass ratio of the mixture of the organic electron transporting material and the organometal halide perovskite material is 1:0.5 to 1:50; and
wherein the thickness of the electron transporting layer is between 10 to 100 nm.

12. The OLED display device according to claim 11, wherein the material of the organic electron transporting material is selected from metal complex material or imidazoles electron transporting material.

13. The OLED display device according to claim 11, wherein the structural formula of the organometallic halide perovskite material is: CH₃NH₃PbA₃, wherein A is selected from one or a combination of Chlorine, Bromine, or Iodine.
